(19) United States
(12) Patent Application Publication
(10) Pub. No.: US 2026/0320273 A1
(43) Pub. Date: Oct. 15, 2026

(54) SYNCHRONOUS CIRCUIT AND SYNCHRONOUS METHOD

(71) Applicant: Montage Technology Co., Ltd., Shanghai (CN)

(72) Inventors: JinFeng Ji, Shanghai (CN); Tao Zhou, Shanghai (CN)

(73) Assignee: Montage Technology Co., Ltd., Shanghai (CN)

(21) Appl. No.: 19/455,652

(22) Filed: Jan. 21, 2026

(30) Foreign Application Priority Data
Apr. 10, 2025 (CN) 202510449987.3

(51) Int. Cl. G06F 30/34

(52) U.S. Cl. CPC G06F 30/34

(57) ABSTRACT

A synchronous circuit includes a producer module configured to: query whether a logical value of a flag stored in a target producer flag register among a plurality of producer flag registers is an empty logical value, in response to the logical value being the empty logical value, set the logical value and a read logical value read from the target producer flag register to an active logical value with a time length of a first cycle, and provide a target flag active signal to a consumer module with a time length of a second cycle. The target flag active signal is configured to indicate that the logical value of the flag stored in the target producer flag register is set to the active logical value.

### CROSS-REFERENCE TO RELATED APPLICATION

This application claims the priority benefit of China application serial no. 202510449987.3, filed on April 10, 2025. The entirety of the above-mentioned patent application is hereby incorporated by reference herein and made a part of this specification.

### BACKGROUND

### Technical Field

The disclosure relates to the field of integrated circuit technology, and in particular, relates to a synchronous circuit and a synchronous method.

### Description of Related Art

Generally, circuits, such as application-specific integrated circuits (ASICs), include various components and various resources, and each component may use the resources to perform various operations. To ensure that these resources can be shared safely and efficiently and to avoid data corruption or circuit instability caused by multiple components accessing the same resource simultaneously, a circuit must have a complete synchronization mechanism. The main function of the synchronization mechanism is to coordinate the access of different components to the shared resources and determine which component has exclusive access to a specific resource at a specific moment, so as to ensure data consistency and correct operation of the circuit.

In ASIC design, flags are often used to achieve synchronization between different logics of the circuit. The flags are used to indicate the state of shared resources. A producer in the circuit is responsible for setting flags, and a consumer in the circuit is responsible for clearing the flags. However, in an actual large-scale chip design, the producer and the consumer may be distributed in different design modules, and these modules are physically distant in the chip floorplan layout. This long-distance communication introduces significant signal propagation delay, making the querying/setting operations and querying/clearing operations on the flags unable to be completed within the same clock cycle, thus failing to ensure the atomicity of flag operations. In addition, at high clock frequencies, querying/setting/clearing a specific flag from numerous flags usually involves complex multiplexing (Mux) and demultiplexing (DeMux) operations. These operations introduce additional delay, so synchronization efficiency is further reduced. Therefore, a low-delay and efficient synchronous circuit is needed.

### SUMMARY

The disclosure provides a synchronous circuit and a synchronous method to solve the communication delay problem between a producer and a consumer and improve the synchronization rate between the two.

According to an embodiment of the disclosure, a synchronous circuit includes a producer module. The producer module is configured to: query whether a logical value of a flag stored in a target producer flag register among a plurality of producer flag registers is an empty logical value, in response to the logical value of the flag stored in the target producer flag register being the empty logical value, set the logical value of the flag stored in the target producer flag register to an active logical value with a time length of a first cycle, set a read logical value read from the target producer flag register to the active logical value with the time length of the first cycle, and provide a target flag active signal to a consumer module with a time length of a second cycle. The target flag active signal is configured to indicate that the logical value of the flag stored in the target producer flag register is set to the active logical value.

According to an embodiment of the disclosure, a synchronous method is applied to a synchronous circuit, and the method is executed by a producer module and includes the following steps. It is queried whether a logical value of a flag stored in a target producer flag register among a plurality of producer flag registers is an empty logical value. In response to the logical value of the flag stored in the target producer flag register being the empty logical value, the logical value of the flag stored in the target producer flag register and a read logical value read from the target producer flag register are set to an active logical value with a time length of a first cycle. A target flag active signal is provided to a consumer module with a time length of a second cycle. The target flag active signal is configured to indicate that the logical value of the flag stored in the target producer flag register is set to the active logical value.

Based on the above, even when the number of flags increases, the operating frequency of the circuit accessing the flags accelerates, or the physical layout distance between the producer module and the consumer module increases, the operations of various components within the circuit may still achieve good synchronization through the flag mechanism.

### BRIEF DESCRIPTION OF THE DRAWINGS

FIG. 1 is a schematic diagram of a synchronous circuit according to an embodiment of the disclosure.

FIGS. 2A and 2B are schematic diagrams of a synchronous circuit according to an embodiment of the disclosure.

FIG. 3 is a flow chart of a synchronous method according to an embodiment of the disclosure.

### DESCRIPTION OF THE EMBODIMENTS

The implementation of the disclosure is illustrated below by specific embodiments. A person having ordinary skill in the art can easily understand other advantages and effects of the present application from the content disclosed in this specification. The disclosure can also be implemented or applied through other different specific implementation ways. The details in this specification can also be modified or changed based on different viewpoints and applications without departing from the spirit of the disclosure. Note that the following embodiments and the features in the embodiments may be combined with each other in the case of no conflict.

It should be noted that the drawings provided in the following embodiments are merely schematically illustrating the basic idea of the disclosure. Therefore, the drawings only show components related to the disclosure rather than drawings which are depicted according to the numbers, shapes, and sizes of the components in actual implementation. In actual implementation, the types, numbers, and proportions of the components can be changed arbitrarily, and the component layout type may also be more complex.

As the scale of chips increases, the synchronous design and management of flags become complex. On one hand, the long distance between a producer and a consumer causes propagation delay. On the other hand, the increase in the number of flags or the acceleration of the operating frequency of the circuit accessing the flags increases the difficulty for the circuit to achieve synchronization in the same cycle.

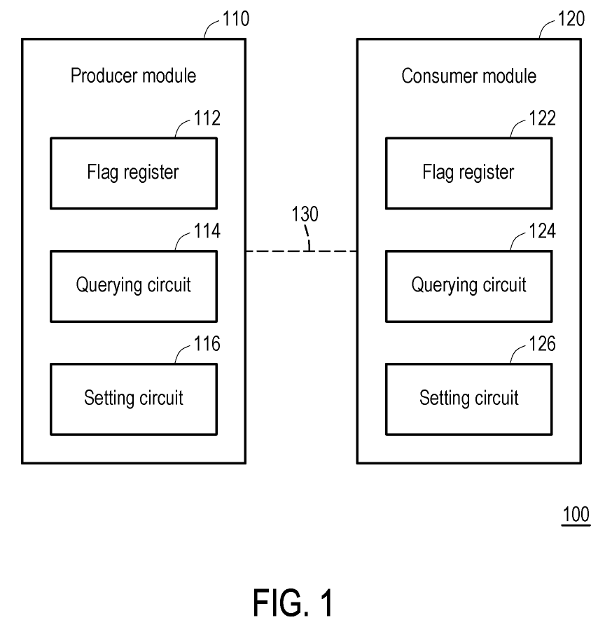

In response to the above problems, the disclosure provides a synchronous circuit and a synchronous method, in which shadow flag registers are added in a producer and a consumer, and a synchronous path is established between these two shadow flag registers (hereinafter also referred to as flag registers, such as flag registers 112 and 122 in FIG. 1). That is, when the producer and consumer perform flag setting, clearing, or querying operations, they may complete the operations locally directly through their respective local shadow flag registers, thereby making the communication delay between the producer and consumer controllable. In this way, it is ensured that the flag-related operations performed internally by the producer and the consumer are synchronized, thereby achieving synchronization of the operations between various components.

In addition, in the disclosure, forwarding logic is introduced in a pipeline of flag querying, setting, and clearing operations. In this way, even if the number of flags increases or the operating frequency of the circuit accessing the flags accelerates, the operations of various components within the circuit may still achieve good synchronization.

The synchronous circuit and synchronous method provided by the disclosure are described in detail in the following paragraphs with reference to the accompanying drawings.

FIG. 1 is a schematic diagram of a synchronous circuit according to an embodiment of the disclosure. Referring to FIG. 1, a synchronous circuit 100 includes a producer module 110, a consumer module 120, and a transmission circuit 130. The producer module 110 includes a flag register 112, a querying circuit 114, and a setting circuit 116. Further, the consumer module 120 includes a flag register 122, a querying circuit 124, and a setting circuit 126.

It should be noted that for the sake of brevity, only one flag register 112 and one flag register 122 are shown in the figure. However, the number of flag register 112 and the number of flag register 122 may be multiple to store multiple flags, which is not limited by the embodiments of the disclosure.

In addition, also for the sake of brevity, the producer module 110 and the consumer module 120 may each include components with the same names. However, for clarity, each component included in the producer module 110 may be added with the prefix "producer", while each component included in the consumer module 120 may be added with the prefix "consumer". For instance, the flag register 112 may be referred to as the producer flag register 112, while the flag register 122 may be referred to as the consumer flag register 122. This naming method may be applicable to all components in the disclosure, and description thereof is not repeated in detail in the following paragraphs.

In an embodiment, the flag register 112 and the flag register 122 may respectively store flags in the producer module 110 and the consumer module 120. The flags are used to indicate the state of associated resources, such as whether the resources are empty or are occupied. For instance, the flags may include two logical values, namely an active logical value and an empty logical value. The active logical value (e.g., 1) indicates that the resource associated with the flag (hereinafter referred to as "associated resource") has been occupied, and the empty logical value (e.g., 0) indicates that the associated resource is in an empty state and may be used. The design of the flag registers 112 and 122 in the disclosure allows flag querying, setting, and clearing operations to be performed locally.

The querying circuit 114 and the querying circuit 124 may be respectively used to query the logical values of the flags stored in the flag register 112 and the flag register 122, as a basis for subsequent operations. The setting circuit 116 and the setting circuit 126 may be respectively used to set, clear, or query the logical values of the flags stored in the flag register 112 and the flag register 122. The transmission circuit 130 may perform signal transmission between the producer module 110 and the consumer module 120, so as to achieve flag state synchronization between the producer module 110 and the consumer module 120.

Assuming that there are 2048 flag registers 112 and a querying operation requires 2 cycles, that is, a time length required to obtain a logical value of one flag from the flag registers 112 is 2 cycles. Further, the transmission circuit 130 may be configured to perform signal transmission between the producer module 110 and the consumer module 120 with a time length of 3 cycles. That is, the time length required to transmit a signal from the producer module 110 to the consumer module 120 (or from the consumer module 120 to the producer module 110) is 3 cycles. The flag synchronization mechanism according to the embodiments of the disclosure is described in the following paragraphs by taking the 7^{th} flag register (which may also be referred to as a target flag register) among the 2048 flag registers 112 as an example.

Before accessing the resource associated with the flag in the 7^{th} flag register, the querying circuit 114 of the producer module 110 may use a time length of 2 cycles (which may also be referred to as a first cycles) to query whether the logical value of the flag stored in the 7^{th} flag register in the flag register 112 is the empty logical value, so as to determine whether the associated resource may be accessed. When it is determined that the state of the associated resource is accessible and after the associated resource is ready, the setting circuit 116 may set the logical value of the flag stored in the 7^{th} flag register to the active logical value, where the time length required for the setting operation is the same as the querying operation (i.e., 2 cycles).

It is worth noting that since the querying circuit 114 relies on a query result from 2 cycles ago when determining the state of the associated resource, during these 2 cycles, other operations may have already changed the state of the associated resource. In other words, during these 2 cycles, the logical value of the flag stored in the 7^{th} flag register may have already been updated to the active logical value from the empty logical value, while a signal carrying the previous (2 cycles ago) query result (the state still being the empty logical value, and this signal is also referred to as a read logical value) is still being transmitted on a pipeline path. Therefore, to avoid competition hazards, after the associated resource is ready, the setting circuit 116 may use the same time length (i.e., 2 cycles) to uniformly set (or update) both the read logical value and the logical value of the flag stored in the 7^{th} flag register to the active logical value, and thus ensuring the atomicity and exclusivity of this operation.

In addition, via the transmission circuit 130, information indicating that the associated resource is ready (e.g., a target flag active signal) may be provided from the producer module 110 to the consumer module 120. As mentioned above, the transmission circuit 130 may use a time length of 3 cycles (which may also be referred to as a second cycle) to transmit the information indicating that the associated resource is ready from the producer module 110 to the consumer module 120.

In other words, the producer module 110 may be configured to query whether the logical value of the flag stored in a target flag register (which may also be referred to as a target producer flag register) among the plurality of flag registers 112 is the empty logical value. Further, in response to the logical value of the flag stored in the target flag register being the empty logical value, the producer module 110 may be configured to set the logical value of the flag stored in the target flag register to the active logical value with the time length of the first cycle. Meanwhile, the producer module 110 may be configured to update the read logical value read from the target flag register to the active logical value with the time length of the second cycle. At the same time, the producer module 110 may be configured to provide the target flag active signal to the consumer module 120 through the transmission circuit 130 with the time length of the second cycle. The target flag active signal may be configured to indicate that the logical value in the flag stored in the target flag register has been set to the active logical value. On the other hand, the consumer module 120 may be configured to receive the target flag active signal from the producer module 110. In addition, the transmission circuit 130 may be configured to provide the target flag active signal provided by the producer module 110 to the consumer module 120 with the time length of the second cycle and provide a target flag empty signal provided by the consumer module 120 to the producer module 110 with the time length of the second cycle. The target flag empty signal may be configured to indicate that the logical value of the flag stored in the target flag register has been updated to the empty logical value.

The setting circuit 116 sets the logical value of the flag stored in the local flag register 112 and the read logical value that has been read from the flag register 112 for the same cycle (i.e., the first cycle). Further, the transmission circuit 130 performs signal transmission between the producer module 110 and the consumer module 120 with a controllable cycle (i.e., the second cycle). In this way, even when the number of flags is numerous, the flags are accessed at high-frequency circuit operating speeds, or the producer module 110 and the consumer module 120 are located far apart in the actual circuit layout, the operation of each component in the circuit may still achieve good synchronization by adjusting the time lengths of the first cycle and the second cycle of the flag mechanism setting.

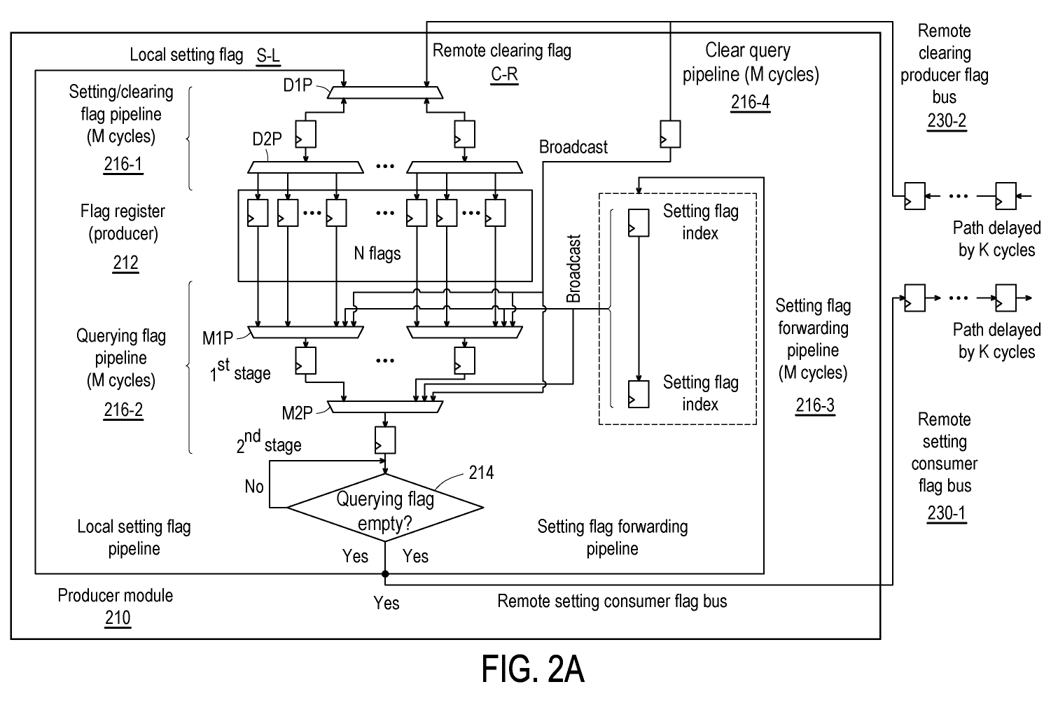

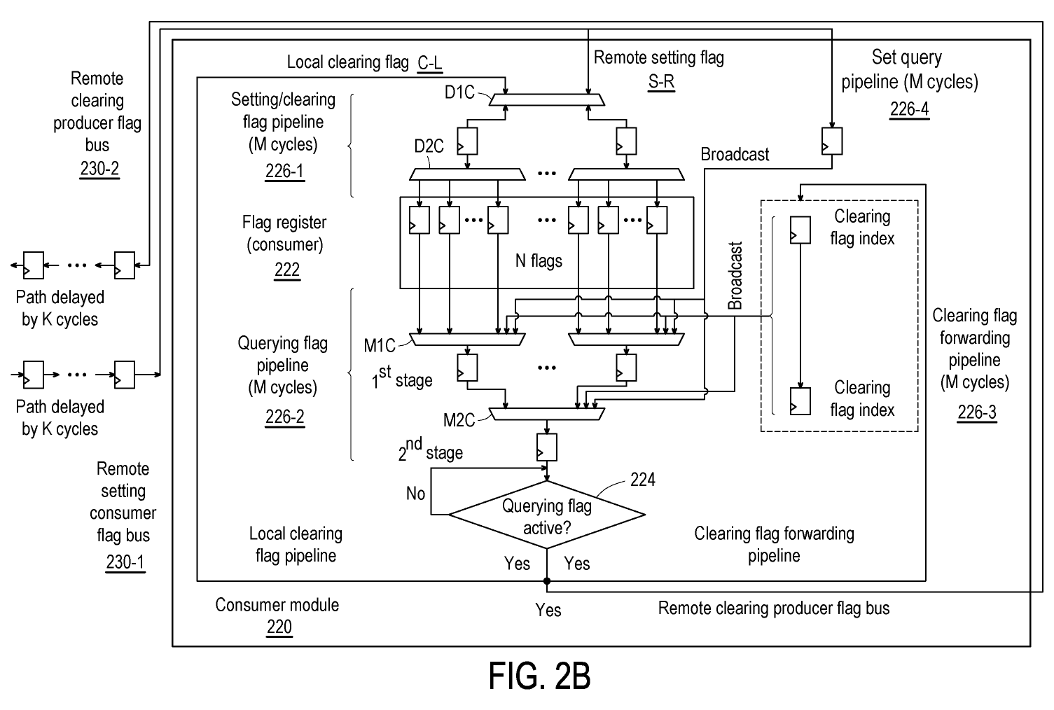

FIGS. 2A and 2B are schematic diagrams of a synchronous circuit according to an embodiment of the disclosure. Referring to FIGS. 1, 2A, 2B, a synchronous circuit of FIGS. 2A and 2B is an implementation of the synchronous circuit 100 of FIG. 1. FIGS. 2A and 2B respectively show a producer module 210 and a consumer module 220, and the producer module 210 and the consumer module 220 may respectively correspond to the producer module 110 and the consumer module 120 of FIG. 1. The producer module 210 and the consumer module 220 may transmit signals via transmission circuits 230-1 and 230-2 (which may also be referred to as a remote setting consumer flag bus 230-1 and a remote clearing producer flag bus 230-2), and the transmission circuits 230-1 and 230-2 may correspond to the transmission circuit 130 of FIG. 1. However, the disclosure is not limited thereto.

First, referring to FIG. 2A, the producer module 210 may include a plurality of flag registers 212, a querying circuit 214, setting circuits 216-1, 216-2, 216-3, and 216-4 (which may also be referred to as a setting/clearing flag pipeline 216-1, a querying flag pipeline 216-2, a setting flag forwarding pipeline 216-3, and a clear query pipeline 216-4). Further, the setting circuit 216-1 may include a demultiplexer D1P, a demultiplexer D2P, and a plurality of demultiplexing registers. Similarly, the setting circuit 216-2 may include a multiplexer M1P, a multiplexer M2P, and a plurality of multiplexing registers. In addition, the producer module 210 may transmit signals to the consumer module 220 via the transmission circuit 230-1 and receive signals from the consumer module 220 via the transmission circuit 230-2.

That is, the flag register 212 of FIG. 2A may correspond to the flag register 112 of FIG. 1. Further, the querying circuit 214 of FIG. 2A may correspond to the querying circuit 114 of FIG. 1. Moreover, the setting circuits 216-1, 216-2, 216-3, and 216-4 of FIG. 2A may correspond to the setting circuit 116 of FIG. 1. However, the disclosure is not limited thereto.

As shown in FIG. 2A, the number of flag register 212 may be N (N is an integer greater than or equal to 1), and a time length required for the setting circuits 216-1, 216-2, 216-3, and 216-4 to perform a flag setting, clearing, or querying operation is M cycles (M is an integer greater than or equal to 1). In an embodiment, the number of N may be 2048, and the number of M may be 2. That is, the number of flag registers 212 may be 2048, and the time length required for the setting circuits 216-1, 216-2, 216-3, and 216-4 to perform a flag setting, clearing, or query operation is 2 cycles. In addition, corresponding to 2 cycles, the setting circuits 216-1 and 216-2 may respectively be 2-stage circuits. However, the disclosure is not limited thereto.

Similar to the description of FIG. 1, before accessing a specific resource, the querying circuit 214 may query, via the querying flag pipeline 216-2, whether the logical value of the flag stored in the target flag register among the flag registers 212 used to indicate the state of the specific resource is an empty logical value. If the query result is no (representing that the resource is still occupied), the querying circuit 214 may continuously perform the querying until the logical value of the flag stored in the target flag register is updated to the empty logical value. If the query result is yes (representing that the resource is empty), as shown below the querying circuit 214 in FIG. 2A, the querying circuit 214 may provide the query result to 3 locations. These 3 locations are a local setting flag pipeline (i.e., the setting/clearing flag pipeline 216-1), the setting flag forwarding pipeline 216-3, and the remote setting consumer flag bus 230-1.

The querying circuit 214 provides the query result to setting/clearing flag pipeline 216-1, so as to set the logical value of the flag stored in the local target flag register to the active logical value. The querying circuit 214 provides the query result to the setting flag forwarding pipeline 216-3, so as to update the signal (i.e., the read logical value) that is already in the pipeline path (i.e., the querying flag pipeline 216-2) and carries the previous query result to the active logical value. In addition, the querying circuit 214 provides the query result to the remote setting consumer flag bus 230-1, so as to update the logical value of the flag stored in the corresponding target flag register (also referred to as the target consumer flag register) in the consumer module 220.

That is, the producer module 210 may, based on the query result of the local querying circuit 214, update the logical value of the flag stored in the target flag register in the local producer module 210, the logical value of the flag in the querying flag pipeline 216-2 (i.e., the read logical value), the logical value of the flag in the setting flag forwarding pipeline 216-3 (the dashed box in the figure), and the logical value of the flag stored in the corresponding target flag register in the remote consumer module 220 to the active logical value. In this way, both the local end (i.e., the producer module 210) and the remote end (i.e., the consumer module 220) may know the state of the resource via the flags in their respective flag registers, and good synchronization is thereby achieved.

Specifically, the setting circuit 216-1 may use a time length of M cycles to set the logical value of the flag stored in the target flag register in the flag register 212 to the active logical value via the demultiplexers D1P and D2P and the demultiplexing register between the demultiplexers D1P and D2P. It should be noted that the operation performed by the setting circuit 216-1 herein (i.e., setting the logical value of the flag stored in the target flag register to the active logical value based on the local signals) may be referred to as a local setting flag S-L. Further, the setting circuit 216-3 may use the time length of M cycles to update the logical value of the flag in the target flag register in setting flag forwarding pipeline 216-3 to the active logical value. Next, the setting circuit 216-3 may use the time length of M cycles to broadcast the logical value of the flag of the target flag register in the setting flag forwarding pipeline 216-3 to each stage of the setting circuit 216-2. Next, the setting circuit 216-2 may, based on the received information in the setting flag forwarding pipeline 216-3, immediately (not M cycles) update the signal that is already in the querying flag pipeline 216-2 and carries the previous query result to the active logical value via the multiplexer M1P and M2P and the multiplexing registers between the multiplexers M1P and M2P. In addition, the transmission circuit 230-1 may use a time length of K (K is an integer greater than or equal to 1) cycles to provide the target flag active signal to the consumer module 220 via the multiple transmission registers. After receiving the target flag active signal, the consumer module 220 may update the logical value of the flag stored in the corresponding local target flag register to the active logical value based on the target flag active signal.

On the other hand, the consumer module 220 may clear the flag after completing the task (i.e., set the logical value of the flag stored in the target flag register in a plurality of flag registers 222 to the empty logical value). Further, the consumer module 220 provides the target flag empty signal to the producer module 210 via the transmission circuit 230-2. After receiving the target flag empty signal, the producer module 210 may update the logical value of the flag stored in the local target flag register to the empty logical value based on the target flag empty signal.

Specifically, the transmission circuit 230-2 may provide the target flag empty signal to the setting circuits 216-1 and 216-4. The setting circuit 216-1 may use the time length of M cycles to set the logical value of the flag stored in the target flag register in the flag register 212 to the empty logical value via the demultiplexer D1P and D2P and the demultiplexing register between the demultiplexers D1P and D2P. It should be noted that the operation performed by the setting circuit 216-1 herein (i.e., setting the logical value of the flag stored in the target flag register to the empty logical value based on the remote signal) may be referred to as a remote clearing flag C-R. Further, the setting circuit 216-4 may use the time length of M cycles to broadcast the target flag empty signal to each stage of the setting circuit 216-2. Next, the setting circuit 216-2 may, based on the received target flag empty signal, immediately (not M cycles) update the signal (i.e., the read logical value) that is already in the querying flag pipeline 216-2 and carries the previous query result to the empty logical value via the multiplexer M1P and M2P and the multiplexing registers between the multiplexers M1P and M2P.

That is, the setting circuits 216-1, 216-2, and 216-4 of the producer module 210 may update both the logical value of the flag stored in the target flag register in the local producer module 210 and the read logical value in the querying flag pipeline 216-2 to the empty logical values based on the target flag empty signal of the remote consumer module 220. In this way, both the local end (i.e., the producer module 210) and the remote end (i.e., the consumer module 220) may know the state of the resource via the flags in their respective flag registers, and good synchronization is thereby achieved.

In an embodiment, the transmission circuit 230-1 and the transmission circuit 230-2 may be unidirectional transmission buses, and the target flag active signal transmitted by the transmission circuit 230-1 and the target flag empty signal transmitted by the transmission circuit 230-2 are two independent signals.

In another embodiment, the transmission circuit 230-1 and the transmission circuit 230-2 may be integrated into one bidirectional transmission bus, and the target flag active signal transmitted by the transmission circuit 230-1 and the target flag empty signal transmitted by the transmission circuit 230-2 may be integrated into one target flag signal. Further, the target flag signal may include 3 pieces of information, which are bus valid information, flag state (op_sel) information, and flag index (flag_idx) information. A width of a value of the bus valid information may be 1 bit. Moreover, a value of 1 for the bus valid information may indicate that the bus is available, and a value of 0 for the bus valid information may indicate that the bus is not available. Similarly, a width of a value of the flag state information may be 1 bit. Further, a value of 1 for the flag state information may indicate that the flag is active (i.e., the logical value of the flag is set to the active logical value), and a value of 0 for the flag state information may indicate that the flag is cleared (i.e., the logical value of the flag is set to the empty logical value). A width of a value of the flag index information may be log2(N) bits, where N is the number of flags. Moreover, the value of the flag index information may indicate a flag register of a specific index among the N flag registers 212 or N flag registers 222, i.e., the target flag register. However, the disclosure is not limited thereto.

Next, referring to FIG. 2B, the consumer module 220 may include the plurality of flag registers 222, a querying circuit 224, and setting circuits 226-1, 226-2, 226-3, and 226-4 (which may also be referred to as a setting/clearing flag pipeline 226-1, a querying flag pipeline 226-2, a clearing flag forwarding pipeline 226-3, and a set query pipeline 226-4). Further, the setting circuit 226-1 may include a demultiplexer D1C, a demultiplexer D2C, and a plurality of demultiplexing registers. Similarly, the setting circuit 226-2 may include a multiplexer M1C, a multiplexer M2C, and a plurality of multiplexing registers. In addition, the consumer module 220 may transmit signals to the producer module 210 via the transmission circuit 230-2 and receive signals from the producer module 210 via the transmission circuit 230-1.

That is, the flag register 222 of FIG. 2B may correspond to the flag register 122 of FIG. 1. Further, the querying circuit 224 of FIG. 2B may correspond to the querying circuit 124 of FIG. 1. Moreover, the setting circuits 226-1, 226-2, 226-3, and 226-4 of FIG. 2B may correspond to the setting circuit 126 of FIG. 1. However, the disclosure is not limited thereto.

As shown in FIG. 2B, the number of flag registers 222 may be N, and the time length required for the setting circuits 226-1, 226-2, 226-3, and 226-4 to perform a flag setting, clearing, or querying operation is M cycles. In an embodiment, the number of N may be 2048, and the number of M may be 2. That is, the number of flag registers 222 may be 2048, and the time length required for the setting circuits 226-1, 226-2, 226-3, and 226-4 to perform a flag setting, clearing, or query operation is 2 cycles. In addition, corresponding to 2 cycles, the setting circuits 226-1 and 226-2 may respectively be 2-stage circuits. However, the disclosure is not limited thereto.

It should be noted that the producer module 210 of FIG. 2A and the consumer module 220 of FIG. 2B are symmetric circuits. The difference between the producer module 210 of FIG. 2A and the consumer module 220 of FIG. 2B mainly lies in that the producer module 210 is configured to set flags (i.e., set the logical value of the flag stored in the target flag register to the active logical value), while the consumer module 220 is configured to clear flags (i.e., set the logical value of the flag stored in the target flag register to the empty logical value).

Similar to the description of FIG. 2A, before using a specific resource, the querying circuit 224 may query, via the querying flag pipeline 226-2, whether the logical value of the flag stored in the target flag register among the flag registers 222 that indicate the state of the specific resource is the active logical value. If the query result is no (representing that the resource has not been available), the querying circuit 224 may continuously perform the querying until the logical value of the flag stored in the target flag register is updated to the active logical value. If the query result is yes, as shown below the querying circuit 224 in FIG. 2B, the querying circuit 224 may provide the query result to 3 locations. These 3 locations are a local clearing flag pipeline (i.e., the setting/clearing flag pipeline 226-1), the clearing flag forwarding pipeline 226-3, and the remote clearing producer flag bus 230-2.

The querying circuit 224 provides the query result to the setting/clearing flag pipeline 226-1, so as to set the logical value of the flag stored in the target flag register among the local flag registers 222 to the empty logical value. The querying circuit 224 provides the query result to the clearing flag forward pipeline 226-3 to update the signal that is already in the pipeline path (i.e., the querying flag pipeline 226-2) and carries the previous query result to the empty logical value. The querying circuit 224 provides the query result to the remote clearing producer flag bus 230-2 to update the logical value of the flag stored in the corresponding target flag register in the producer module 210.

That is, the consumer module 220 may, based on the query result of the local querying circuit 224, update the logical value of the flag stored in the target flag register in the local consumer module 220, the logical value of the flag in the querying flag pipeline 226-2 (i.e., the read logical value), the logical value of the flag in the clearing flag forwarding pipeline 226-3 (the dashed box in the figure), and the logical value of the flag stored in the corresponding target flag register in the remote producer module 210 to the empty logical values. In this way, both the local end (i.e., the consumer module 220) and the remote end (i.e., the producer module 210) may know the state of the resource via the flags in their respective flag registers, and good synchronization is thereby achieved.

Specifically, the setting circuit 226-1 may use the time length of M cycles to set the logical value of the flag stored in the target flag register among the flag registers 222 to the empty logical value via the demultiplexer D1C and D2C and the demultiplexing register between the demultiplexers D1C and D2C. It should be noted that the operation performed by the setting circuit 226-1 herein (i.e., setting the logical value of the flag stored in the target flag register to the empty logical value based on the local signal) may be referred to as a local clearing flag C-L. Further, the setting circuit 226-3 may use the time length of M cycles to update the logical value of the flag in the target flag register in the clearing flag forwarding pipeline 226-3 to the empty logical value. Next, the setting circuit 226-3 may use the time length of M cycles to broadcast the logical value of the flag in the target flag register in the clearing flag forwarding pipeline 226-3 to each stage of the setting circuit 226-2. Next, the setting circuit 226-2 may, based on the received information in the clearing flag forwarding pipeline 226-3, update the signal that is already in the querying flag pipeline 226-2 and carries the previous query result to the empty logical value immediately (not M cycles) via the multiplexer M1C and M2C and the multiplexing registers between the multiplexers M1C and M2C. In addition, the transmission circuit 230-2 may use the time length of K cycles to provide the target flag empty signal to the producer module 210 via the transmission registers. After receiving the target flag empty signal, the producer module 210 may update the logical value of the flag stored in the corresponding local target flag register to the empty logical value based on the target flag empty signal.

On the other hand, the producer module 210 may set a flag when it learns that a specific resource needs to be accessed (i.e., setting the logical value of the flag stored in the local target flag register to the active logical value). Further, the producer module 210 may provide a target flag active signal to the consumer module 220 via the transmission circuit 230-1. After receiving the target flag active signal, the consumer module 220 may update the logical value of the flag stored in the local target flag register to the active logical value based on the target flag active signal.

Specifically, the transmission circuit 230-1 may provide the target flag active signal to the setting circuits 226-1 and 226-4. The setting circuit 226-1 may use the time length of M cycles to set the logical value of the flag stored in the target flag register among the flag registers 222 to the active logical value via the demultiplexers D1C and D2C and the demultiplexing registers between the demultiplexers D1C and D2C. It should be noted that the operation performed by the setting circuit 226-1 herein (i.e., setting the logical value of the flag in the target flag register to the active logical value based on the remote signal) may be referred to as a remote setting flag S-R. Further, the setting circuit 226-4 may use the time length of M cycles to broadcast the target flag active signal to each stage in the setting circuit 226-2. Next, the setting circuit 226-2 may, based on the received target flag active signal, update the signal that is already in the querying flag pipeline 226-2 and carries the previous query result to the active logical value immediately (not M cycles) via the multiplexers M1C and M2C and the multiplexing registers between the multiplexers M1C and M2C.

That is, the setting circuits 226-1, 226-2, and 226-4 of the consumer module 220 may update both the logical value of the flag stored in the target flag register in the local consumer module 220 and the read logical value in the querying flag pipeline 226-2 to the active logical value based on the target flag active signal from the remote producer module 210. In this way, both the local end (i.e., the consumer module 220) and the remote end (i.e., the producer module 210) may know the state of the resource via the flags in their respective flag registers, and good synchronization is thereby achieved.

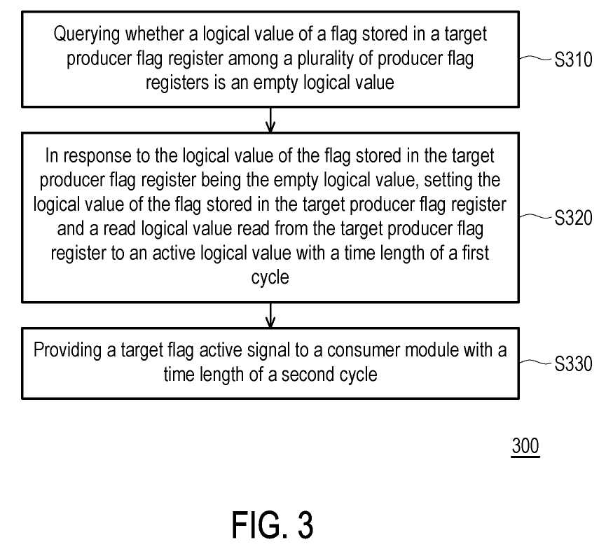

FIG. 3 is a flow chart of a synchronous method according to an embodiment of the disclosure. Referring to FIGS. 1 and 3, a synchronous method 300 includes the following steps.

Through the producer module 110, in step S310, it may be queried whether the logical value of the flag stored in the target flag register among the plurality of flag registers 112 is the empty logical value. In step S320, in response to the logical value of the flag stored in the target flag register being the empty logical value, the logical value of the flag stored in the target flag register and the read logical value read from the target flag register may be set to the active logical value with the time length of the first cycle. In step S330, the target flag active signal may be provided to the consumer module 120 with the time length of the second cycle.

In this way, even when the number of flags is numerous or the flags are accessed at high-frequency circuit operating speeds, the operations of various components within the circuit may still achieve good synchronization via the flag mechanism.

In addition, the implementation details of the synchronous method 300 may refer to the description of FIGS. 1-2B to obtain sufficient teaching, suggestions, and implementation of the embodiments, and description of these details is not repeated herein.

Based on the above, when the producer module 110 and the consumer module 120 perform flag setting, clearing, or querying, they may directly complete these operations locally via the local flag registers, thereby making the flag-related operations performed internally by the producer module 110 and the consumer module 120 respectively synchronous. Moreover, the transmission circuit 130 between the producer module 110 and the consumer module 120 makes the delay caused by the inter-module distances generated after the circuit physical layout controllable, thereby making operations between various components synchronous. In this way, even when the number of flags increases, the operating frequency of the circuit accessing the flags accelerates, or the physical distance between the producer module and the consumer module is excessively large, the operations of various components within the circuit may still achieve good synchronization via the flag mechanism.

In view of the foregoing, through the above improvements, the atomicity of flag operations is ensured and efficiency of synchronous pipelines are achieved when the number of flags is excessive or the circuit operating frequency is high in the disclosure, without the introduction of pipeline bubbles due to delays. Through this design, resource synchronization efficiency and overall performance of large-scale ASICs are significantly improved.

Finally, it is worth noting that the foregoing embodiments are merely described to illustrate the technical means of the disclosure and should not be construed as limitations of the disclosure. Even though the foregoing embodiments are referenced to provide detailed description of the disclosure, people having ordinary skill in the art should understand that various modifications and variations can be made to the technical means in the disclosed embodiments, or equivalent replacements may be made for part or all of the technical features; nevertheless, it is intended that the modifications, variations, and replacements shall not make the nature of the technical means to depart from the scope of the technical means of the embodiments of the disclosure.

What is claimed is:

1. A synchronous circuit, comprising:
a producer module, configured to:
query whether a logical value of a flag stored in a target producer flag register among a plurality of producer flag registers of the producer module is an empty logical value,
in response to the logical value of the flag stored in the target producer flag register being the empty logical value,
set the logical value of the flag stored in the target producer flag register to an active logical value with a time length of a first cycle,
set a read logical value read from the target producer flag register to the active logical value with the time length of the first cycle, and
provide a target flag active signal to a consumer module with a time length of a second cycle, wherein the target flag active signal is configured to indicate that the logical value of the flag stored in the target producer flag register is set to the active logical value.

2. The synchronous circuit according to claim 1, wherein the consumer module is configured to:
receive the target flag active signal, and based on the target flag active signal,
set a logical value of a flag stored in a target consumer flag register among a plurality of consumer flag registers of the consumer module to the active logical value with the time length of the first cycle, and
set a read logical value read from the target consumer flag register to the active logical value with the time length of the first cycle.

3. The synchronous circuit according to claim 1, wherein the producer module comprises:
the plurality of producer flag registers, configured to store a plurality of flags;
a querying circuit, configured to query whether the logical value of the flag stored in the target producer flag register among the plurality of producer flag registers is the empty logical value; and
a setting circuit, configured to: in response to the logical value of the flag stored in the target producer flag register being the empty logical value, set the logical value of the flag stored in the target producer flag register and the read logical value read from the target producer flag register to the active logical value.

4. The synchronous circuit according to claim 3, wherein the setting circuit comprises:
a setting/clearing flag pipeline, configured to: in response to the logical value of the flag stored in the target producer flag register being the empty logical value, set the logical value of the flag stored in the target producer flag register to the active logical value, and in response to a target flag empty signal from the consumer module, set the logical value of the flag stored in the target producer flag register to the empty logical value;
a querying flag pipeline, configured to: read the read logical value from the target producer flag register and transmit the read logical value to the querying circuit, so that the querying circuit determines the logical value of the flag stored in the target producer flag register according to the read logical value;
a setting flag forwarding pipeline, configured to: in response to the logical value of the flag stored in the target producer flag register being the empty logical value, update the read logical value in the querying flag pipeline to the active logical value; and
a clear query pipeline, configured to: in response to the target flag empty signal from the consumer module, update the read logical value in the querying flag pipeline to the empty logical value.

5. The synchronous circuit according to claim 4, wherein
the setting/clearing flag pipeline comprises a plurality of demultiplexers and a plurality of demultiplexing registers, and
the querying flag pipeline comprises a plurality of multiplexers and a plurality of multiplexing registers.

6. The synchronous circuit according to claim 4, wherein the setting flag forwarding pipeline is further configured to: update the logical value of the flag stored in the target producer flag register in the setting flag forwarding pipeline to the active logical value, and broadcast the updated logical value of the flag stored in the target producer flag register in the setting flag forwarding pipeline to each stage of the querying flag pipeline, so as to update the read logical value in the querying flag pipeline to the active logical value.

7. The synchronous circuit according to claim 4, wherein the clear query pipeline is further configured to: broadcast the target flag empty signal to each stage of the querying flag pipeline, so as to update the read logical value in the querying flag pipeline to the empty logical value.

8. The synchronous circuit according to claim 1, wherein the consumer module is configured to:
query whether a logical value of a flag stored in a target consumer flag register among a plurality of consumer flag registers of the consumer module is the active logical value,
in response to the logical value of the flag stored in the target consumer flag register being the active logical value,
set the logical value of the flag stored in the target consumer flag register to the empty logical value with the time length of the first period,
set a read logical value read from the target consumer flag register to the empty logical value with the time length of the first period, and
provide a target flag empty signal to the producer module with the time length of the second period, wherein the target flag empty signal is configured to indicate that the logical value of the flag stored in the target consumer flag register is set to the empty logical value.

9. The synchronous circuit according to claim 8, wherein the producer module is further configured to:
receive the target flag empty signal, and based on the target flag empty signal,
set the logical value of the flag stored in the target producer flag register to the empty logical value with the time length of the first period, and
set the read logical value read from the target producer flag register to the empty logical value with the time length of the first period.

10. The synchronous circuit according to claim 8, comprising a transmission circuit comprising:
a remote setting consumer flag bus, configured to: provide the target flag active signal to the consumer module with the time length of the second period; and
a remote clearing producer flag bus, configured to: provide the target flag empty signal to the producer module with the time length of the second period.

11. A synchronous method, applied to a synchronous circuit and comprising:
executing, by a producer module:
querying whether a logical value of a flag stored in a target producer flag register among a plurality of producer flag registers is an empty logical value;
in response to the logical value of the flag stored in the target producer flag register being the empty logical value, setting the logical value of the flag stored in the target producer flag register and a read logical value read from the target producer flag register to an active logical value with a time length of a first cycle; and
providing a target flag active signal to a consumer module with a time length of a second cycle, wherein the target flag active signal is configured to indicate that the logical value of the flag stored in the target producer flag register is set to the active logical value.
